(19) United States
(12) Patent Application Publication
(10) Pub. No.: US 2024/0422968 A1
(43) Pub. Date: Dec. 19, 2024

(54) STACK PROCESS-BASED THREE-DIMENSIONAL FLASH MEMORY AND MANUFACTURING METHOD THEREFOR

(71) Applicant: IUCF-HYU (Industry-University Cooperation Foundation Hanyang University), Seoul (KR)

(72) Inventor: Yun Heub SONG, Seoul (KR)

(21) Appl. No.: 18/822,290

(22) Filed: Sep. 2, 2024

Related U.S. Application Data
(63) Continuation of application No. PCT/KR2023/004272, filed on Mar. 30, 2023.

(30) Foreign Application Priority Data
Apr. 5, 2022 (KR) 10-2022-0041979

(51) Int. Cl. H10B 41/27; H01L 23/538

(52) U.S. Cl. CPC H10B 41/27; H01L 23/5384; H01L 23/5386

(57) ABSTRACT

A stack process-based three-dimensional flash memory and a manufacturing method therefor are disclosed. According to an embodiment, the three-dimensional flash memory may comprise: a first memory block including first vertical channel structures formed to extend in a vertical direction on a first substrate; a second memory block including second vertical channel structures formed to extend in a vertical direction on a second substrate; and a connection pad for connecting the first memory block and the second memory block to each other.

### TECHNICAL FIELD

The following embodiments related to a three-dimensional flash memory and a method of manufacturing the same, and more particularly, to a technology using a stack process.

### BACKGROUND ART

A flash memory device that is an electrically erasable programmable read only memory (EEPROM) electrically controlling data input/output through an F—N (Fowler-Nordheim) tunneling or a hot electron injection may be used in common in a computer, a digital camera, an MP3 player, a game system, a memory stick, etc.

In this flash memory device, it is required to increase the degree of integration to satisfy excellent performance and low price demanded by consumers, and thus a three-dimensional structure in which memory cell transistors are vertically arranged to constitute a cell string has been proposed.

A stack process of stacking stack structures in a vertical direction is used to manufacture a three-dimensional flash memory.

However, because a three-dimensional flash memory according to the related art is formed by simply stacking stack structures including vertical channel structures in a vertical direction, memory cell characteristics due to length extension of the vertical channel structures are degraded as the number of stacked stack structures is increased, and complexity of a process of connecting the vertical channel structures of the stack structures is increased.

Thus, the following embodiments propose a technology of solving the described problems and disadvantages.

### DETAILED DESCRIPTION OF THE INVENTION

### Technical Problem

To solve the problem of degradation of memory cell characteristics due to extension of a length of vertical channel structures and the disadvantage of an increase in complexity in a process of connecting the vertical channel structures of stack structures, embodiments propose a three-dimensional flash memory having a structure in which a first memory block including first vertical channel structures formed to extend in a vertical direction on a first substrate and a second memory block including second vertical channel structures formed to extend in the vertical direction on a second substrate are connected to each other through a connection pad, and a method of manufacturing the same.

In particular, embodiments propose a three-dimensional flash memory in which a connection wiring line of a bit line of the first memory block and a connection wiring line of a bit line of the second memory block are included in a connection pad, and thus the connection pad functions as a connection wiring line in addition to connection between the memory blocks, and a method of manufacturing the same.

However, technical problems to be solved by the present disclosure are not limited to the above problems and may be variously expanded without departing from the technical spirit and scope of the present disclosure.

### Technical Solution

According to an embodiment, a three-dimensional flash memory based on a stack process includes a first memory block including first vertical channel structures formed to extend in a vertical direction on a first substrate, a second memory block including second vertical channel structures formed to extend the vertical direction on a second substrate, and a connection pad connecting the first memory block and the second memory block arranged such that at least one first bit line connected to the first vertical channel structures and at least one second bit line connected to the second vertical channel structures face each other.

According to an embodiment, a three-dimensional flash memory based on a stack process includes a first memory block including first vertical channel structures formed to extend in a vertical direction on a first substrate, a second memory block including second vertical channel structures formed to extend in the vertical direction on a second substrate, and a connection pad connecting the first memory block and the second memory block arranged such that the first substrate and the second substrate face each other.

According to an aspect, the connection pad may include a connection wiring line of the at least one first bit line connected to the first vertical channel structures and a connection wiring line of the at least one second bit line connected to the second vertical channel structures.

According to another aspect, the connection pad may be commonly provided with the connection wiring line of the at least one first bit line connected to the first vertical channel structures and the connection wiring line of the at least one second bit line connected to the second vertical channel structures.

According to still another aspect, the connection pad may connect the first memory block and the second memory block to each other through bonding or connect the first memory block and the second memory block to each other through a through silicon via (TSV).

### Advantageous Effects of the Invention

Embodiments may propose a three-dimensional flash memory in which a first memory block including first vertical channel structures formed to extend in a vertical direction on a first substrate and a second memory block including second vertical channel structures formed to extend in the vertical direction on a second substrate are connected to each other through a connection pad, and a method of manufacturing the same, and thus the problem of degradation of memory cell characteristics due to extension of a length of vertical channel structures and the disadvantage of an increase in complexity in a process of connecting the vertical channel structures of stack structures may be solved.

In particular, embodiments may propose a three-dimensional flash memory in which a connection wiring line of a bit line of the first memory block and a connection wiring line of a bit line of the second memory block are included in the connection pad, and thus the connection pad functions as a connection wiring line in addition to connection between the memory blocks, and a method of manufacturing the same.

However, effects of the present disclosure are not limited to the above effects and may be variously expanded without departing from the technical spirit and scope of the present disclosure.

### DESCRIPTION OF THE DRAWINGS

FIG. 1 is a cross-sectional view illustrating a structure of a three-dimensional flash memory according to an embodiment.

FIG. 2 is an enlarged cross-sectional view illustrating a connection pad included in the three-dimensional flash memory illustrated in FIG. 1.

FIG. 3 is a cross-sectional view illustrating a structure of a three-dimensional flash memory according to another embodiment.

FIG. 4 is an enlarged cross-sectional view illustrating a connection pad included in the three-dimensional flash memory illustrated in FIG. 3.

FIG. 5 is a flowchart illustrating a method of manufacturing the three-dimensional flash memory according to the embodiment.

FIGS. 6A and 6B are cross-sectional views for describing the method of manufacturing the three-dimensional flash memory illustrated in FIG. 5.

FIG. 7 is a flowchart illustrating a method of manufacturing the three-dimensional flash memory according to another embodiment.

FIGS. 8A and 8B are cross-sectional views for describing the method of manufacturing the three-dimensional flash memory illustrated in FIG. 7.

### BEST MODE

Hereinafter, embodiments of the present disclosure will be described in detail with reference to the accompanying drawing. However, the present disclosure is not restricted or limited by the embodiments. Further, the same reference numerals in each drawing indicate the same components.

Further, terms used in the specification are used to properly express the embodiments of the present disclosure, and the terms may change depending on the intention of a viewer or an operator or customs in the field to which the present disclosure belongs. Therefore, definitions of these terms should be made based on the content throughout the specification. For example, in the specification, a singular form also includes a plural form unless specifically mentioned in a phrase. Further, the term “comprise” and/or “comprising” used herein does not exclude the presence or addition of one or more other components, steps, operations, and/or elements in or to components, steps, operations, and/or elements mentioned above. Further, even though the terms such as first and second are used in the specification to describe various areas, directions, and shapes, the areas, directions, and shapes should not be limited by these terms. These terms are merely used to distinguish one area, direction or shape from another area, direction or shape. Thus, a portion/part referred to as a “first part/portion” in an embodiment may be referred to as a “second part/portion” in another embodiment.

Further, it should be understood that various embodiments of the present disclosure are different from each other but are not necessarily mutually exclusive. For example, specific shapes, specific structures, and specific characteristics described herein may be implemented in another embodiment without departing from the technical spirit and scope of the present disclosure in relation to the embodiment. Further, it should be understood that positions, arrangements, or configurations of individual components in the range of each presented embodiment may be changed without departing from the technical spirit and scope of the present disclosure.

Hereinafter, a three-dimensional flash memory and a method of manufacturing the same according to embodiments will be described in detail with reference to the accompanying drawings.

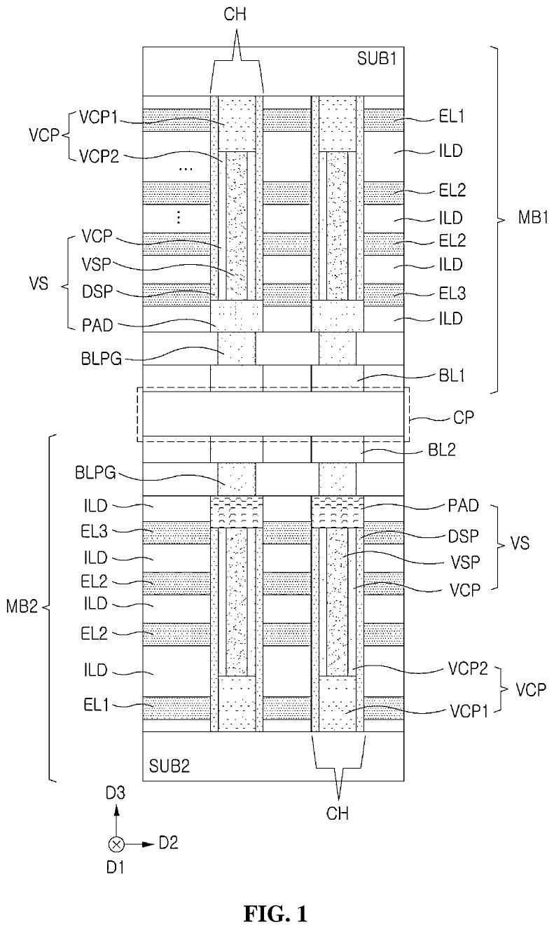

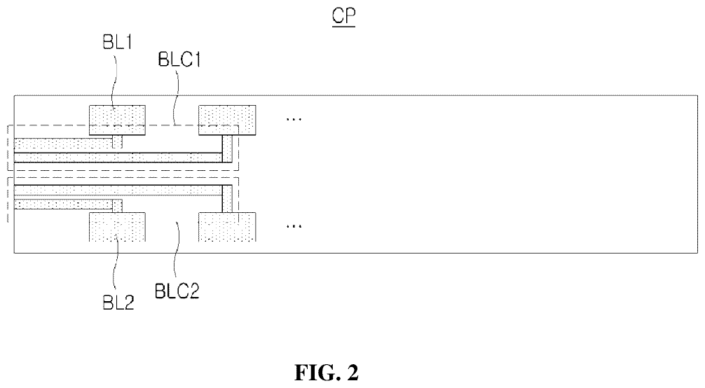

FIG. 1 is a cross-sectional view illustrating a structure of a three-dimensional flash memory according to an embodiment, and FIG. 2 is an enlarged cross-sectional view illustrating a connection pad included in the three-dimensional flash memory illustrated in FIG. 1.

Referring to FIGS. 1 and 2, the three-dimensional flash memory according to an embodiment may include a first memory block MB1 including first vertical channel structures VS1 formed to extend in a vertical direction (e.g., a third direction D3) on a first substrate SUB1, a second memory block MB2 including second vertical channel structures VS2 formed to extend in the vertical direction (e.g., the third direction D3) on a second substrate SUB2, and a connection pad CP connecting the first memory block MB1 and the second memory block MB2 to each other.

Each of the first substrate SUB1 and the second substrate SUB2 may be a semiconductor substrate such as a silicon substrate, a silicon-germanium substrate, a germanium substrate, or a monocrystalline epitaxial layer grown on a monocrystalline silicon substrate. Each of the first substrate SUB1 and the second substrate SUB2 may be doped with a first conductive type impurity (e.g., a P-type impurity).

Stack structures ST may be arranged on each of the first substrate SUB1 and the second substrate SUB2. The stack structures ST may be two-dimensionally arranged in a second direction D2 while extending in a first direction D1. Further, the stack structures ST may be spaced apart from each other in the second direction D2.

Each of the stack structures ST may include gate electrodes EL1, EL2, and EL3 alternately stacked in the vertical direction (e.g., the third direction D3) perpendicular to upper surfaces of the first substrate SUB1 and the second substrate SUB2, and interlayer insulating films ILD. The stack structures ST may have substantially flat upper surfaces. That is, the upper surfaces of the stack structures ST may be parallel to the upper surfaces of the first substrate SUB1 and the second substrate SUB2. Hereinafter, the vertical direction means the third direction D3 or a direction opposite to the third direction D3.

In each of the first memory block MB1 and the second memory block MB2, the gate electrodes EL1, EL2, and EL3 may be one of an erase control line ECL, ground selection lines GSL0, GSL1, and GSL2, word lines WL0 to WLn and DWL, first string selection lines SSL1-1, SSL1-2, and SSL1-3, and second string selection lines SSL2-1, SSL2-2, and SSL2-3 that are sequentially stacked on each of the first substrate SUB1 and the second substrate SUB2.

Each of the gate electrodes EL1, EL2, and EL3 may have substantially the same thickness in the third direction D3 while extending in the first direction D1. Hereinafter, the thickness means a thickness in the third direction D3. Each of the gate electrodes EL1, EL2, and EL3 may be formed of a conductive material. For example, each of the gate electrodes EL1, EL2, and EL3 may include at least one selected from a doped semiconductor (e.g., a doped silicon or the like), a metal (e.g., W (tungsten), Cu (copper), Al (aluminum), Ti (titanium), Ta (tantalum), Mo (molybdenum), Ru (ruthenium), Au (gold), or the like), a conductive metal nitride (e.g., a titanium nitride, a tantalum nitride, or the like) or the like. Each of the gate electrodes EL1, EL2, and EL3 may include at least one of all metal materials that may be formed by ALD in addition to the metal material described above.

In more detail, the gate electrodes EL1, EL2, and EL3 may include the lowermost first gate electrode EL1, the uppermost third gate electrode EL3, and the plurality of second gate electrodes EL2 between the first gate electrode EL1 and the third gate electrode EL3. Although each of the first gate electrode EL1 and the third gate electrode EL3 is illustrated and described in a singular number, this is illustrative, and the present disclosure is not limited thereto. As needed, the plurality of first gate electrodes EL1 and the plurality of third gate electrodes EL3 may also be provided. The first gate electrode EL1 may correspond to one of the ground selection lines GSL0, GSL1, and GSL2. The second gate electrode EL2 may correspond to any one of the word lines WL0 to WLn and DWL. The third gate electrode EL3 may correspond to any one of the first string selection lines SSL1-1, SSL1-2, and SSL1-3 or any one of the second string selection lines SSL2-1, SSL2-2, and SSL2-3.

Although not illustrated, an end of each of the stack structures ST may have a stepwise structure in the first direction D1. In more detail, the gate electrodes EL1, EL2, and EL3 of the stack structures ST may have a length in the first direction D1, which decreases as distances from the first substrate SUB1 and the second substrate SUB2 increase. The third gate electrode EL3 may have the smallest length in the first direction D1 and the largest distance spaced apart from the first substrate SUB1 and the second substrate SUB2 in the third direction D3. The first gate electrode EL1 may have the largest length in the first direction D1 and the smallest distance spaced apart from the first substrate SUB1 and the second substrate SUB2 in the third direction D3. Due to the stepwise structure, the thickness of each of the stack structures ST may decrease as a distance from the outermost one of vertical channel structures VS, which will be described below, increases, and side walls of the gate electrodes EL1, EL2, and EL3 may be spaced apart from each other at regular intervals in the first direction D1 when viewed from a plane.

In each of the first memory block MB1 and the second memory block MB2, the interlayer insulating films ILD may have different thicknesses. As an example, the lowermost one and the uppermost one of the interlayer insulating films ILD may have a thickness that is smaller than those of the other interlayer insulating films ILD. However, this is illustrative, and the present disclosure is not limited thereto. The interlayer insulating films ILD may be set to have different thickness or the same thickness according to characteristics of a semiconductor device. The interlayer insulating films ILD may be formed of an insulating material to insulate the gate electrodes EL1, EL2, and EL3 from each other. As an example, the interlayer insulating films ILD may be formed of a silicon oxide.

Each of the first memory block MB1 and the second memory block MB2 may be provided with a plurality of channel holes CH passing through portions of the stack structures ST and the substrate SUB. The vertical channel structures VS may be provided in the channel holes CH. The vertical channel structures VS, which are a plurality of cell strings CSTR, may be formed to extend in the third direction D3 while connected to the substrate SUB. Connection of the vertical channel structures VS to each of the first substrate SUB1 and the second substrate SUB2 may be achieved as a lower surface of a portion of each of the vertical channel structures VS comes into contact with an upper surface of each of the first substrate SUB1 and the second substrate SUB2, but the present disclosure is not limited or restricted thereto, and the connection may be achieved as the lower surface of the portion of each of the vertical channel structures VS is buried into each of the first substrate SUB1 and the second substrate SUB2. When the portion of each of the vertical channel structures VS is buried into each of the first substrate SUB1 and the second substrate SUB2, the lower surfaces of the vertical channel structures VS may be positioned at a level lower than the upper surface of each of the first substrate SUB1 and the second substrate SUB2.

A plurality of columns of vertical channel structures VS passing through one of the stack structures ST of each of the first memory block MB1 and the second memory block MB2 may be provided. For example, the three columns of the vertical channel structures VS may pass through one of the stack structures ST. However, the present disclosure is not restricted or limited thereto, and the two columns of the vertical channel structures VS may pass through one of the stack structures ST or four or more columns of the vertical channel structures VS may pass through one of the stack structures ST. In a pair of adjacent columns, the vertical channel structures VS corresponding to one column may be shifted in the first direction D1 from the vertical channel structures VS corresponding to the other column adjacent thereto. When viewed from a plane, the vertical channel structures VS may be arranged in a zigzag shape in the first direction D1. However, the present disclosure is not restricted or limited thereto, and the vertical channel structures VS may form an array in which the vertical channel structures VS are arranged side by side in rows and columns.

In each of the first memory block MB1 and the second memory block MB2, the vertical channel structures VS may be formed to extend in the third direction D3 from the first substrate SUB1 and the second substrate SUB2. It is illustrated in the drawings that each of the vertical channel structures VS has a column shape having the same width at an upper end and a lower end thereof, but the present disclosure is not restricted or limited thereto, and each of the vertical channel structures VS may have a shape of which widths in the first direction D1 and the second direction D2 increase toward the third direction D3. An upper surface of each of the vertical channel structures VS may have a circular shape, an elliptical shape, a quadrangular shape, or a bar shape.

In each of the first memory block MB1 and the second memory block MB2, each of the vertical channel structures VS may include a data storage pattern DSP, a vertical channel pattern VCP, a vertical semiconductor pattern VSP, and a conductive pad PAD. In each of the vertical channel structures VS, the data storage pattern DSP may have a pipe shape or macaroni shape with an opened lower end, and the vertical channel pattern VCP may have a pipe shape or a macaroni shape with a closed lower end. The vertical semiconductor pattern VSP may fill a space surrounded by the vertical channel pattern VCP and the conductive pad PAD.

While covering inner walls of the channel holes CH, the data storage pattern DSP may inwardly surround an outer wall of the vertical channel pattern VCP and may be outwardly in contact with the side walls of the gate electrodes EL1, EL2, and EL3. Accordingly, areas of the data storage pattern DSP, which correspond to the second gate electrodes EL2, together with areas of the vertical channel pattern VCP, which correspond to the second gate electrodes EL2, may constitute memory cells in which a memory operation (e.g., a program operation, a reading operation, or an erasure operation) is performed by voltages applied through the second gate electrodes EL2. The memory cells correspond to memory cell transistors MCT. That is, the data storage pattern DSP may trap charges or holes by the voltages applied through the second gate electrodes EL2 or may maintain states of the charges (e.g., polarization states of the charges) by the voltages applied through the second gate electrodes EL2, and thus, the data storage pattern DSP may serve as data storage in the three-dimensional flash memory. For example, a tunneling oxide film (oxide)-charge storage film (nitride)-blocking oxide (oxide) (ONO) layer or a ferroelectric layer may be used as the data storage pattern DSP. The data storage pattern DSP may indicate a binary data value or a multi-value data value through a change in the amount of trapped charges or holes or may indicate the binary data value or the multi-value data value through a state change of the charges.

The vertical channel pattern VCP may cover an inner wall of the data storage pattern DSP. The vertical channel pattern VCP may include a first part VCP1 and a second part VCP2 on the first part VCP1.

The first part VCP1 of the vertical channel pattern VCP may be provided under each of the channel holes CH and may be in contact with each of the first substrate SUB1 and the second substrate SUB2. The first part VCP1 of the vertical channel pattern VCP may be used to block, suppress, or minimize a leakage current in each of the vertical channel structures VS and/or used as an epitaxial pattern. A thickness of the first part VCP1 of the vertical channel pattern VCP may be greater than, for example, a thickness of the first gate electrode EL1. A side wall of the first part VCP1 of the vertical channel pattern VCP may be surrounded by the data storage pattern DSP. An upper surface of the first part VCP1 of the vertical channel pattern VCP may be positioned at a higher level than that of an upper surface of the first gate electrode EL1. In more detail, the upper surface of the first part VCP1 of the vertical channel pattern VCP may be positioned between the upper surface of the first gate electrode EL1 and a lower surface of the lowermost one of the second gate electrodes EL2. A lower surface of the first part VCP1 of the vertical channel pattern VCP may be positioned at a lower level than an uppermost surface of the substrate SUB (i.e., a lower surface of the lowermost one of the interlayer insulating films ILD). A portion of the first part VCP1 of the vertical channel pattern VCP may overlap the first gate electrode EL1 in a horizontal direction. Hereinafter, the horizontal direction refers to a predetermined direction extending on a plane parallel to the first direction D1 and the second direction D2.

The second part VCP2 of the vertical channel pattern VCP may extend from the upper surface of the first part VCP1 in the third direction D3. The second part VCP2 of the vertical channel pattern VCP may be provided between the data storage pattern DSP and the vertical semiconductor pattern VSP and may correspond to the second gate electrodes EL2. Accordingly, as described above, the second part VCP2 of the vertical channel pattern VCP may constitute the memory cells together with the areas of the data storage pattern DSP, which correspond to the second gate electrodes EL2.

An upper surface of the second part VCP2 of the vertical channel pattern VCP may be substantially coplanar with an upper surface of the vertical semiconductor pattern VSP. The upper surface of the second part VCP2 of the vertical channel pattern VCP may be positioned at a level higher than the upper surface of the uppermost one of the second gate electrodes EL2. In more detail, the upper surface of the second part VCP2 of the vertical channel pattern VCP may be positioned between an upper surface and a lower surface of the third gate electrode EL3.

The vertical channel pattern VCP, which is a component for transferring charges or holes to the data storage pattern DSP, may be formed of monocrystalline silicon or polysilicon such that a channel is formed or boosted by the voltage applied thereto. However, the present disclosure is not restricted or limited thereto. For example, the vertical channel pattern VCP may be formed of an oxide semiconductor material capable of blocking, suppressing, or minimizing a leakage current. For example, the vertical channel pattern VCP may be formed of an oxide semiconductor material including at least one of In, Zn, and Ga having excellent leakage current characteristics or a group 4 semiconductor material. The vertical channel pattern VCP may be formed of, for example, a ZnOx-based material including AZO, ZTO, IZO, ITO, IGZO, or Ag—ZnO. Thus, the vertical channel pattern VCP may block, suppress, or minimize a leakage current to the gate electrodes EL1, EL2, and EL3 or the substrate SUB, may improve transistor characteristics (e.g., a threshold voltage distribution and a program/read operation speed) of at least one of the gate electrodes EL1, EL2, and EL3, and as a result, may improve electrical characteristics of the three-dimensional flash memory.

The vertical semiconductor pattern VSP may be surrounded by the second part VCP2 of the vertical channel pattern VCP. The upper surface of the vertical semiconductor pattern VSP may be in contact with the conductive pad PAD, and a lower surface of the vertical semiconductor pattern VSP may be in contact with the first part VCP1 of the vertical channel pattern VCP. The vertical semiconductor pattern VSP may be spaced apart from the first substrate SUB1 and the second substrate SUB2 in the third direction D3. In other words, the vertical semiconductor pattern VSP may be electrically floating from the first substrate SUB1 and the second substrate SUB2.

The vertical semiconductor pattern VSP may be formed of a material that helps diffusion of charges or holes in the vertical channel pattern VCP. In more detail, the vertical semiconductor pattern VSP may be formed of a material having excellent charge and hole mobility. For example, the vertical semiconductor pattern VSP may be formed of a semiconductor material doped with impurities, an intrinsic semiconductor material not doped with impurities, or a polycrystalline semiconductor material. In more detail, for example, the vertical semiconductor pattern VSP may be formed of polysilicon doped with a first conductive type impurity (e.g., a P-type impurity) that is the same as the first substrate SUB1 and the second substrate SUB2. That is, the vertical semiconductor pattern VSP may improve the electrical characteristics of the three-dimensional flash memory to increase a memory operation speed.

The vertical channel structures VS may correspond to channels of an erasure control transistor ECT, first and second string selection transistors SST1 and SST2, a ground selection transistor GST, and the memory cell transistors MCT.

The conductive pad PAD may be provided on the upper surface of the second part VCP2 of the vertical channel pattern VCP and on the upper surface of the vertical semiconductor pattern VSP. The conductive pad PAD may be connected to an upper portion of the vertical channel pattern VCP and an upper portion of the vertical semiconductor pattern VSP. A side wall of the conductive pad PAD may be surrounded by the data storage pattern DSP. An upper surface of the conductive pad PAD may be substantially coplanar with an upper surface of each of the stack structures ST (i.e., an upper surface of the uppermost one of the interlayer insulating films ILD). A lower surface of the conductive pad PAD may be positioned at a lower level than that of an upper surface of the third gate electrode EL3. In more detail, the lower surface of the conductive pad PAD may be positioned between the upper surface and the lower surface of the third gate electrode EL3. That is, at least a portion of the conductive pad PAD may overlap the third gate electrode EL3 in the horizontal direction.

In each of the first memory block MB1 and the second memory block MB2, the conductive pad PAD may be formed of a semiconductor doped with impurities or a conductive material. For example, the conductive pad PAD may be formed of a semiconductor material doped with impurities different from those of the vertical semiconductor pattern VSP (in more detail, second conductive type (e.g., N-type) impurities different from the first conductive type (e.g., P-type) impurities).

The conductive pad PAD may reduce contact resistance between a bit line BL, which will be described below, and the vertical channel pattern VCP (or the vertical semiconductor pattern VSP).

Hereinafter, it has been described that the vertical channel structures VS have a structure including the conductive pad PAD, but the present disclosure is not restricted or limited thereto, and the vertical channel structures VS may have a structure in which the conductive pad PAD is omitted. In this case, as the conductive pad PAD is omitted from the vertical channel structures VS, each of the vertical channel pattern VCP and the vertical semiconductor pattern VSP may extend in the third direction D3 so that the upper surface of each of the vertical channel pattern VCP and the vertical semiconductor pattern VSP is substantially coplanar with the upper surface of each of the stack structures ST (i.e., the upper surface of the uppermost one of the interlayer insulating films ILD). Further, in this case, a bit line contact plug BLPG, which will be described below, may be in direct contact with and electrically connected to the vertical channel pattern VCP instead of being indirectly electrically connected to the vertical channel pattern VCP through the conductive pad PAD.

Further, it has been described that the vertical channel structures VS include the vertical semiconductor pattern VSP, but the present disclosure is not restricted or limited thereto, and the vertical semiconductor pattern VSP may be omitted.

Further, it has been described that the vertical channel pattern VCP has a structure including the first part VCP1 and the second part VCP2, but the present disclosure is not restricted or limited thereto, and the vertical channel pattern VCP may have a structure in which the first part VCP1 is excluded. For example, the vertical channel pattern VCP may be provided between the vertical semiconductor pattern VSP and the data storage pattern DSP that are formed to extend to the first substrate SUB1 and the second substrate SUB2 and may be formed to extend to the first substrate SUB1 and the second substrate SUB2 such that the vertical channel pattern VCP is in contact with the first substrate SUB1 and the second substrate SUB2. In this case, the lower surface of the vertical channel pattern VCP may be positioned at a level lower than the uppermost surface (e.g., a lower surface of the lowermost one of the interlayer insulating films ILD) of each of the first substrate SUB1 and the second substrate SUB2, and the upper surface of the vertical channel pattern VCP may be substantially coplanar with the upper surface of the vertical semiconductor pattern VSP.

In each of the first memory block MB1 and the second memory block MB2, a separation trench TR extending in the first direction D1 may be provided between the adjacent stack structures ST. The separation trench TR may separate and isolate each of the stack structures ST to form a single block.

A common source area CSR may be provided inside each of the first substrate SUB1 and the second substrate SUB2 exposed by the separation trench TR. The common source area CSR may extend in the first direction D1 within each of the first substrate SUB1 and the second substrate SUB2. The common source area CSR may be formed of a semiconductor material doped with the second conductive type impurities (e.g., the N-type impurities). The common source area CSR may correspond to a common source line CSL.

In each of the first memory block MB1 and the second memory block MB2, a common source plug CSP may be provided inside the separation trench TR. The common source plug CSP may be connected to the common source area CSR. An upper surface of the common source plug CSP may be substantially coplanar with the upper surface of each of the stack structures ST (i.e., the upper surface of the uppermost one of the interlayer insulating films ILD). The common source plug CSP may have a plate shape extending in the first direction D1 and the third direction D3. In this case, the common source plug CSP may have a shape of which a width in the second direction D2 increases toward the third direction D3.

In each of the first memory block MB1 and the second memory block MB2, insulation spacers SP may be interposed between the common source plug CSP and the stack structures ST. The insulation spacers SP may be provided between the adjacent stack structures ST to face each other. For example, the insulation spacers SP may be formed of a silicon oxide, a silicon nitride, a silicon oxy nitride, or a low-k material having a low dielectric constant.

In each of the first memory block MB1 and the second memory block MB2, a capping insulating film CAP may be provided on the stack structures ST, the vertical channel structures VS, and the common source plug CSP. The capping insulating film CAP may cover the upper surface of the uppermost one of the interlayer insulating films ILD, the upper surface of the conductive pad PAD, and the upper surface of the common source plug CSP. The capping insulating film CAP may be formed of an insulating material different from that of the interlayer insulating films ILD. The bit line contact plug BLPG electrically connected to the conductive pad PAD may be provided inside the capping insulating film CAP. The bit line contact plug BLPG may have a shape of which widths in the first direction D1 and the second direction D2 increase toward the third direction D3.

In each of the first memory block MB1 and the second memory block MB2, the bit line BL may be provided on the capping insulating film CAP and the bit line contact plug BLPG. The bit line BL may correspond to any one of a plurality of bit lines and may be formed of a conductive material to extend in the first direction D1. The conductive material constituting the bit line BL may be the same material as the conductive material forming each of the gate electrodes EL1, EL2, and EL3.

In each of the first memory block MB1 and the second memory block MB2, the bit line BL may be electrically connected to the vertical channel structures VS through the bit line contact plug BLPG. Here, the fact that the bit line BL is connected to the vertical channel structures VS may mean that the bit line BL is connected to the vertical channel pattern VCP included in the vertical channel structures VS.

In each of the first memory block MB1 and the second memory block MB2, the three-dimensional flash memory having such a structure may perform a program operation, a read operation, and an erase operation based on a voltage applied to each of the cell strings CSTR, a voltage applied to the string selection line SSL, a voltage applied to each of the word lines WL0 to WLn, a voltage applied to the ground selection line GSL, and a voltage applied to the common source line CSL. For example, the three-dimensional flash memory may perform the program operation by forming a channel in the vertical channel pattern VCP and transferring charges or holes to the data storage pattern DSP of a target memory cell, based on the voltage applied to each of the cell strings CSTR, the voltage applied to the string selection line SSL, the voltage applied to each of the word lines WL0 to WLn, the voltage applied to the ground selection line GSL, and the voltage applied to the common source line CSL.

Further, the three-dimensional flash memory according to the embodiment is not limited or restricted to the described structure, and may be implemented in various structures assuming that each of the first memory block MB1 and the second memory block MB2 includes the vertical channel pattern VCP, the data storage pattern DSP, the gate electrodes EL1, EL2, and EL3, the bit line BL, and the common source line CSL according to an implementation.

For example, the three-dimensional flash memory may be implemented in a structure including a back gate BG instead of the vertical semiconductor pattern VSP in contact with an inner wall of the vertical channel pattern VCP. In this case, while at least a portion of the back gate BG is surrounded by the vertical channel pattern VCP to apply a voltage for the memory operation to the vertical channel pattern VCP, the back gate BG may be formed of a conductive material including at least one selected from a doped semiconductor (e.g., a doped silicon or the like), a metal (e.g., W (tungsten), Cu (copper), Al (aluminum), Ti (titanium), Ta (tantalum), Mo (molybdenum), Ru (ruthenium), Au (gold), or the like), a conductive metal nitride (e.g., a titanium nitride, a tantalum nitride, or the like) or the like in the vertical direction (e.g., the third direction D3).

In the three-dimensional flash memory having this structure, the first memory block MB1 and the second memory block MB2 may be arranged such that a first bit line BL1 of the first memory block MB1 and a second bit line BL2 of the second memory block MB2 face each other.

Accordingly, the connection pad CP may connect the first memory block MB1 and the second memory block MB2 arranged such that the bit lines BL1 and BL2 face each other.

In particular, the connection pad CP may include a connection wiring line BLC1 of the first bit line BL1 and a connection wiring line BLC2 of the second bit line BL2.

That is, as illustrated in FIG. 2, the connection pad CP includes the connection wiring line BLC1 of the first bit line BL1 and the connection wiring line BLC2 of the second bit line BL2, and thus the first bit line BL1 of the first memory block MB1 and the second bit line BL2 of the second memory block MB2 may be connected to the connection wiring lines BLC1 and BLC2, and at the same time, the first memory block MB1 and the second memory block MB2 may be connected to each other.

Further, it is illustrated in the drawings that the connection wiring line BLC1 of the first bit line BL1 and the connection wiring line BLC2 of the second bit line BL2 are independently provided on the connection pad CP such that the connection wiring lines BLC1 and BLC2 are distinguished from each other, but the present disclosure is not limited or restricted thereto, and the connection wiring lines BLC1 and BLC2 may be commonly provided. As an example, the connection pad CP may include a common connection wiring line that commonly serves as the connection wiring line BLC1 of the first bit line BL1 and the connection wiring line BLC2 of the second bit line BL2. In this case, the same electrical signal may be applied to the vertical channel structure VS connected to the first bit line BL1 and the vertical channel structure VS connected to the second bit line BL2 at the same timing through the common connection wiring line.

In this case, the connection pad CP may use bonding to connect the first memory block MB1 and the second memory block MB2 to each other. That is, the connection pad CP may connect the first memory block MB1 and the second memory block MB2 to each other through metal bonding. However, the present disclosure is not limited or restricted thereto, and the connection pad CP may connect the first memory block MB1 and the second memory block MB2 to each other through a through silicon via (TSV).

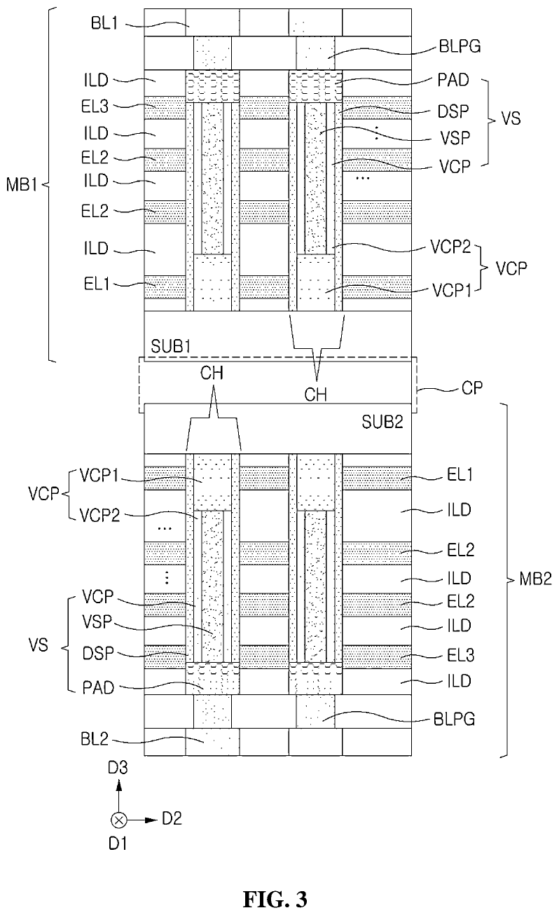

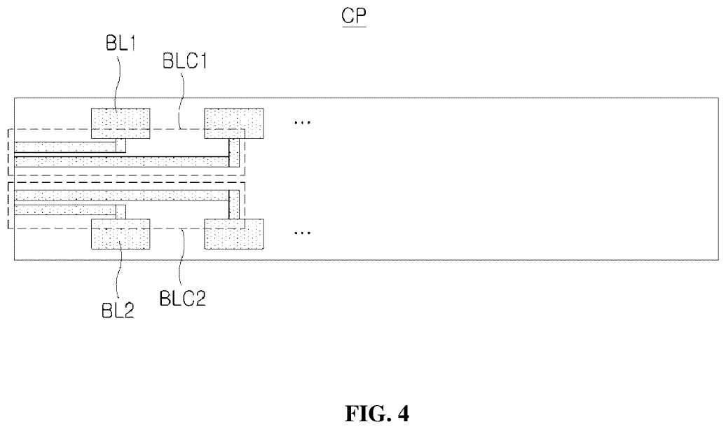

FIG. 3 is a cross-sectional view illustrating a structure of a three-dimensional flash memory according to another embodiment, and FIG. 4 is an enlarged cross-sectional view illustrating a connection pad included in the three-dimensional flash memory illustrated in FIG. 3.

Referring to FIGS. 3 and 4, the three-dimensional flash memory according to another embodiment may include the first memory block MB1 including the first vertical channel structures VS1 formed to extend in the vertical direction (e.g., the third direction D3) on the first substrate SUB1, the second memory block MB2 including the second vertical channel structures VS2 formed to extend in the vertical direction (e.g., the third direction D3) on the second substrate SUB2, and the connection pad CP connecting the first memory block MB1 and the second memory block MB2 to each other.

Each of the first substrate SUB1 and the second substrate SUB2 may be a semiconductor substrate such as a silicon substrate, a silicon-germanium substrate, a germanium substrate, or a monocrystalline epitaxial layer grown on a monocrystalline silicon substrate. Each of the first substrate SUB1 and the second substrate SUB2 may be doped with the first conductive type impurity (e.g., a P-type impurity).

The stack structures ST may be arranged on each of the first substrate SUB1 and the second substrate SUB2. The stack structures ST may be two-dimensionally arranged in the second direction D2 while extending in the first direction D1. Further, the stack structures ST may be spaced apart from each other in the second direction D2.

Each of the stack structures ST may include gate electrodes EL1, EL2, and EL3 alternately stacked in the vertical direction (e.g., the third direction D3) perpendicular to upper surfaces of the first substrate SUB1 and the second substrate SUB2, and interlayer insulating films ILD. The stack structures ST may have substantially flat upper surfaces. That is, the upper surfaces of the stack structures ST may be parallel to the upper surfaces of the first substrate SUB1 and the second substrate SUB2. Hereinafter, the vertical direction means the third direction D3 or a direction opposite to the third direction D3.

In each of the first memory block MB1 and the second memory block MB2, the gate electrodes EL1, EL2, and EL3 may be one of the erase control line ECL, the ground selection lines GSL0, GSL1, and GSL2, the word lines WL0 to WLn and DWL, the first string selection lines SSL1-1, SSL1-2, and SSL1-3, and the second string selection lines SSL2-1, SSL2-2, and SSL2-3 that are sequentially stacked on each of the first substrate SUB1 and the second substrate SUB2.

Each of the gate electrodes EL1, EL2, and EL3 may have substantially the same thickness in the third direction D3 while extending in the first direction D1. Hereinafter, the thickness means a thickness in the third direction D3. Each of the gate electrodes EL1, EL2, and EL3 may be formed of a conductive material. For example, each of the gate electrodes EL1, EL2, and EL3 may include at least one selected from a doped semiconductor (e.g., a doped silicon or the like), a metal (e.g., W (tungsten), Cu (copper), Al (aluminum), Ti (titanium), Ta (tantalum), Mo (molybdenum), Ru (ruthenium), Au (gold), or the like), a conductive metal nitride (e.g., a titanium nitride, a tantalum nitride, or the like) or the like. Each of the gate electrodes EL1, EL2, and EL3 may include at least one of all metal materials that may be formed by ALD in addition to the metal material described above.

In more detail, the gate electrodes EL1, EL2, and EL3 may include the lowermost first gate electrode EL1, the uppermost third gate electrode EL3, and the plurality of second gate electrodes EL2 between the first gate electrode EL1 and the third gate electrode EL3. Although each of the first gate electrode EL1 and the third gate electrode EL3 is illustrated and described in a singular number, this is illustrative, and the present disclosure is not limited thereto. As needed, the plurality of first gate electrodes EL1 and the plurality of third gate electrodes EL3 may also be provided. The first gate electrode EL1 may correspond to one of the ground selection lines GSL0, GSL1, and GSL2. The second gate electrode EL2 may correspond to any one of the word lines WL0 to WLn and DWL. The third gate electrode EL3 may correspond to any one of the first string selection lines SSL1-1, SSL1-2, and SSL1-3 or any one of the second string selection lines SSL2-1, SSL2-2, and SSL2-3.

Although not illustrated, an end of each of the stack structures ST may have a stepwise structure in the first direction D1. In more detail, the gate electrodes EL1, EL2, and EL3 of the stack structures ST may have a length in the first direction D1, which decreases as distances from the first substrate SUB1 and the second substrate SUB2 increase. The third gate electrode EL3 may have the smallest length in the first direction D1 and the largest distance spaced apart from the first substrate SUB1 and the second substrate SUB2 in the third direction D3. The first gate electrode EL1 may have the largest length in the first direction D1 and the smallest distance spaced apart from the first substrate SUB1 and the second substrate SUB2 in the third direction D3. Due to the stepwise structure, the thickness of each of the stack structures ST may decrease as a distance from the outermost one of vertical channel structures VS, which will be described below, increases, and the side walls of the gate electrodes EL1, EL2, and EL3 may be spaced apart from each other at regular intervals in the first direction D1 when viewed from a plane.

In each of the first memory block MB1 and the second memory block MB2, the interlayer insulating films ILD may have different thicknesses. As an example, the lowermost one and the uppermost one of the interlayer insulating films ILD may have a thickness that is smaller than those of the other interlayer insulating films ILD. However, this is illustrative, and the present disclosure is not limited thereto. The interlayer insulating films ILD may be set to have different thickness or the same thickness according to characteristics of a semiconductor device. The interlayer insulating films ILD may be formed of an insulating material to insulate the gate electrodes EL1, EL2, and EL3 from each other. As an example, the interlayer insulating films ILD may be formed of a silicon oxide.

Each of the first memory block MB1 and the second memory block MB2 may be provided with the plurality of channel holes CH passing through portions of the stack structures ST and the substrate SUB. The vertical channel structures VS may be provided in the channel holes CH. The vertical channel structures VS, which are the plurality of cell strings CSTR, may be formed to extend in the third direction D3 while connected to the substrate SUB. Connection of the vertical channel structures VS to each of the first substrate SUB1 and the second substrate SUB2 may be achieved as a lower surface of a portion of each of the vertical channel structures VS comes into contact with an upper surface of each of the first substrate SUB1 and the second substrate SUB2, but the present disclosure is not limited or restricted thereto, and the connection may be achieved as the lower surface of the portion of each of the vertical channel structures VS is buried into each of the first substrate SUB1 and the second substrate SUB2. When the portion of each of the vertical channel structures VS is buried into each of the first substrate SUB1 and the second substrate SUB2, the lower surfaces of the vertical channel structures VS may be positioned at a level lower than the upper surface of each of the first substrate SUB1 and the second substrate SUB2.

A plurality of columns of vertical channel structures VS passing through one of the stack structures ST of each of the first memory block MB1 and the second memory block MB2 may be provided. For example, the three columns of the vertical channel structures VS may pass through one of the stack structures ST. However, the present disclosure is not restricted or limited thereto, and the two columns of the vertical channel structures VS may pass through one of the stack structures ST or four or more columns of the vertical channel structures VS may pass through one of the stack structures ST. In the pair of adjacent columns, the vertical channel structures VS corresponding to one column may be shifted in the first direction D1 from the vertical channel structures VS corresponding to the other column adjacent thereto. When viewed from a plane, the vertical channel structures VS may be arranged in a zigzag shape in the first direction D1. However, the present disclosure is not restricted or limited thereto, and the vertical channel structures VS may form an array in which the vertical channel structures VS are arranged side by side in rows and columns.

In each of the first memory block MB1 and the second memory block MB2, the vertical channel structures VS may be formed to extend in the third direction D3 from the first substrate SUB1 and the second substrate SUB2. It is illustrated in the drawings that each of the vertical channel structures VS has a column shape having the same width at an upper end and a lower end thereof, but the present disclosure is not restricted or limited thereto, and each of the vertical channel structures VS may have a shape of which widths in the first direction D1 and the second direction D2 increase toward the third direction D3. The upper surface of each of the vertical channel structures VS may have a circular shape, an elliptical shape, a quadrangular shape, or a bar shape.

In each of the first memory block MB1 and the second memory block MB2, each of the vertical channel structures VS may include the data storage pattern DSP, the vertical channel pattern VCP, the vertical semiconductor pattern VSP, and the conductive pad PAD. In each of the vertical channel structures VS, the data storage pattern DSP may have a pipe shape or macaroni shape with an opened lower end, and the vertical channel pattern VCP may have a pipe shape or a macaroni shape with a closed lower end. The vertical semiconductor pattern VSP may fill the space surrounded by the vertical channel pattern VCP and the conductive pad PAD.

While covering the inner walls of the channel holes CH, the data storage pattern DSP may inwardly surround the outer wall of the vertical channel pattern VCP and may be outwardly in contact with the side walls of the gate electrodes EL1, EL2, and EL3. Accordingly, areas of the data storage pattern DSP, which correspond to the second gate electrodes EL2, together with areas of the vertical channel pattern VCP, which correspond to the second gate electrodes EL2, may constitute memory cells in which a memory operation (e.g., a program operation, a reading operation, or an erasure operation) is performed by the voltages applied through the second gate electrodes EL2. The memory cells correspond to the memory cell transistors MCT. That is, the data storage pattern DSP may trap charges or holes by the voltages applied through the second gate electrodes EL2 or may maintain states of the charges (e.g., polarization states of the charges) by the voltages applied through the second gate electrodes EL2, and thus, the data storage pattern DSP may serve as data storage in the three-dimensional flash memory. For example, a tunneling oxide film (oxide)-charge storage film (nitride)-blocking oxide (oxide) (ONO) layer or a ferroelectric layer may be used as the data storage pattern DSP. The data storage pattern DSP may indicate the binary data value or the multi-value data value through the change in the amount of trapped charges or holes or may indicate the binary data value or the multi-value data value through the state change of the charges.

The vertical channel pattern VCP may cover the inner wall of the data storage pattern DSP. The vertical channel pattern VCP may include the first part VCP1 and the second part VCP2 on the first part VCP1.

The first part VCP1 of the vertical channel pattern VCP may be provided under each of the channel holes CH and may be in contact with each of the first substrate SUB1 and the second substrate SUB2. The first part VCP1 of the vertical channel pattern VCP may be used to block, suppress, or minimize a leakage current in each of the vertical channel structures VS and/or used as an epitaxial pattern. A thickness of the first part VCP1 of the vertical channel pattern VCP may be greater than, for example, the thickness of the first gate electrode EL1. The side wall of the first part VCP1 of the vertical channel pattern VCP may be surrounded by the data storage pattern DSP. The upper surface of the first part VCP1 of the vertical channel pattern VCP may be positioned at a higher level than that of an upper surface of the first gate electrode EL1. In more detail, the upper surface of the first part VCP1 of the vertical channel pattern VCP may be positioned between the upper surface of the first gate electrode EL1 and the lower surface of the lowermost one of the second gate electrodes EL2. The lower surface of the first part VCP1 of the vertical channel pattern VCP may be positioned at a lower level than the uppermost surface of the substrate SUB (i.e., the lower surface of the lowermost one of the interlayer insulating films ILD). The portion of the first part VCP1 of the vertical channel pattern VCP may overlap the first gate electrode EL1 in a horizontal direction. Hereinafter, the horizontal direction refers to a predetermined direction extending on a plane parallel to the first direction D1 and the second direction D2.

The second part VCP2 of the vertical channel pattern VCP may extend from the upper surface of the first part VCP1 in the third direction D3. The second part VCP2 of the vertical channel pattern VCP may be provided between the data storage pattern DSP and the vertical semiconductor pattern VSP and may correspond to the second gate electrodes EL2.

Accordingly, as described above, the second part VCP2 of the vertical channel pattern VCP may constitute the memory cells together with the areas of the data storage pattern DSP, which correspond to the second gate electrodes EL2.

The upper surface of the second part VCP2 of the vertical channel pattern VCP may be substantially coplanar with the upper surface of the vertical semiconductor pattern VSP. The upper surface of the second part VCP2 of the vertical channel pattern VCP may be positioned at a level higher than the upper surface of the uppermost one of the second gate electrodes EL2. In more detail, the upper surface of the second part VCP2 of the vertical channel pattern VCP may be positioned between the upper surface and the lower surface of the third gate electrode EL3.

The vertical channel pattern VCP, which is a component for transferring charges or holes to the data storage pattern DSP, may be formed of monocrystalline silicon or polysilicon such that a channel is formed or boosted by the voltage applied thereto. However, the present disclosure is not restricted or limited thereto. For example, the vertical channel pattern VCP may be formed of an oxide semiconductor material capable of blocking, suppressing, or minimizing a leakage current. For example, the vertical channel pattern VCP may be formed of an oxide semiconductor material including at least one of In, Zn, and Ga having excellent leakage current characteristics or a group 4 semiconductor material. The vertical channel pattern VCP may be formed of, for example, a ZnOₓ-based material including AZO, ZTO, IZO, ITO, IGZO, or Ag—ZnO. Thus, the vertical channel pattern VCP may block, suppress, or minimize a leakage current to the gate electrodes EL1, EL2, and EL3 or the substrate SUB, may improve transistor characteristics (e.g., the threshold voltage distribution and the program/read operation speed) of at least one of the gate electrodes EL1, EL2, and EL3, and as a result, may improve electrical characteristics of the three-dimensional flash memory.

The vertical semiconductor pattern VSP may be surrounded by the second part VCP2 of the vertical channel pattern VCP. The upper surface of the vertical semiconductor pattern VSP may be in contact with the conductive pad PAD, and the lower surface of the vertical semiconductor pattern VSP may be in contact with the first part VCP1 of the vertical channel pattern VCP. The vertical semiconductor pattern VSP may be spaced apart from the first substrate SUB1 and the second substrate SUB2 in the third direction D3. In other words, the vertical semiconductor pattern VSP may be electrically floating from the first substrate SUB1 and the second substrate SUB2.

The vertical semiconductor pattern VSP may be formed of a material that helps diffusion of charges or holes in the vertical channel pattern VCP. In more detail, the vertical semiconductor pattern VSP may be formed of a material having excellent charge and hole mobility. For example, the vertical semiconductor pattern VSP may be formed of a semiconductor material doped with impurities, an intrinsic semiconductor material not doped with impurities, or a polycrystalline semiconductor material. In more detail, for example, the vertical semiconductor pattern VSP may be formed of polysilicon doped with the first conductive type impurity (e.g., a P-type impurity) that is the same as the first substrate SUB1 and the second substrate SUB2. That is, the vertical semiconductor pattern VSP may improve the electrical characteristics of the three-dimensional flash memory to increase a memory operation speed.

The vertical channel structures VS may correspond to the channels of the erasure control transistor ECT, the first and second string selection transistors SST1 and SST2, the ground selection transistor GST, and the memory cell transistors MCT.

The conductive pad PAD may be provided on the upper surface of the second part VCP2 of the vertical channel pattern VCP and on the upper surface of the vertical semiconductor pattern VSP. The conductive pad PAD may be connected to the upper portion of the vertical channel pattern VCP and the upper portion of the vertical semiconductor pattern VSP. The side wall of the conductive pad PAD may be surrounded by the data storage pattern DSP. The upper surface of the conductive pad PAD may be substantially coplanar with the upper surface of each of the stack structures ST (i.e., the upper surface of the uppermost one of the interlayer insulating films ILD). The lower surface of the conductive pad PAD may be positioned at a lower level than that of the upper surface of the third gate electrode EL3. In more detail, the lower surface of the conductive pad PAD may be positioned between the upper surface and the lower surface of the third gate electrode EL3. That is, at least a portion of the conductive pad PAD may overlap the third gate electrode EL3 in the horizontal direction.

In each of the first memory block MB1 and the second memory block MB2, the conductive pad PAD may be formed of a semiconductor doped with impurities or a conductive material. For example, the conductive pad PAD may be formed of a semiconductor material doped with impurities different from those of the vertical semiconductor pattern VSP (in more detail, second conductive type (e.g., N-type) impurities different from the first conductive type (e.g., P-type) impurities).

The conductive pad PAD may reduce contact resistance between the bit line BL, which will be described below, and the vertical channel pattern VCP (or the vertical semiconductor pattern VSP).

Hereinafter, it has been described that the vertical channel structures VS have a structure including the conductive pad PAD, but the present disclosure is not restricted or limited thereto, and the vertical channel structures VS may have a structure in which the conductive pad PAD is omitted. In this case, as the conductive pad PAD is omitted from the vertical channel structures VS, each of the vertical channel pattern VCP and the vertical semiconductor pattern VSP may extend in the third direction D3 so that the upper surface of each of the vertical channel pattern VCP and the vertical semiconductor pattern VSP is substantially coplanar with the upper surface of each of the stack structures ST (i.e., the upper surface of the uppermost one of the interlayer insulating films ILD). Further, in this case, the bit line contact plug BLPG, which will be described below, may be in direct contact with and electrically connected to the vertical channel pattern VCP instead of being indirectly electrically connected to the vertical channel pattern VCP through the conductive pad PAD.

Further, it has been described that the vertical channel structures VS include the vertical semiconductor pattern VSP, but the present disclosure is not restricted or limited thereto, and the vertical semiconductor pattern VSP may be omitted.

Further, it has been described that the vertical channel pattern VCP has a structure including the first part VCP1 and the second part VCP2, but the present disclosure is not restricted or limited thereto, and the vertical channel pattern VCP may have a structure in which the first part VCP1 is excluded. For example, the vertical channel pattern VCP may be provided between the vertical semiconductor pattern VSP and the data storage pattern DSP that are formed to extend to the first substrate SUB1 and the second substrate SUB2 and may be formed to extend to the first substrate SUB1 and the second substrate SUB2 such that the vertical channel pattern VCP is in contact with the first substrate SUB1 and the second substrate SUB2. In this case, the lower surface of the vertical channel pattern VCP may be positioned at a level lower than the uppermost surface (e.g., the lower surface of the lowermost one of the interlayer insulating films ILD) of each of the first substrate SUB1 and the second substrate SUB2, and the upper surface of the vertical channel pattern VCP may be substantially coplanar with the upper surface of the vertical semiconductor pattern VSP.

In each of the first memory block MB1 and the second memory block MB2, the separation trench TR extending in the first direction D1 may be provided between the adjacent stack structures ST. The separation trench TR may separate and isolate each of the stack structures ST to form a single block.

The common source area CSR may be provided inside each of the first substrate SUB1 and the second substrate SUB2 exposed by the separation trench TR. The common source area CSR may extend in the first direction D1 within each of the first substrate SUB1 and the second substrate SUB2. The common source area CSR may be formed of a semiconductor material doped with the second conductive type impurities (e.g., the N-type impurities). The common source area CSR may correspond to the common source line CSL.

In each of the first memory block MB1 and the second memory block MB2, the common source plug CSP may be provided inside the separation trench TR. The common source plug CSP may be connected to the common source area CSR. The upper surface of the common source plug CSP may be substantially coplanar with the upper surface of each of the stack structures ST (i.e., the upper surface of the uppermost one of the interlayer insulating films ILD). The common source plug CSP may have a plate shape extending in the first direction D1 and the third direction D3. In this case, the common source plug CSP may have a shape of which a width in the second direction D2 increases toward the third direction D3.

In each of the first memory block MB1 and the second memory block MB2, insulation spacers SP may be interposed between the common source plug CSP and the stack structures ST. The insulation spacers SP may be provided between the adjacent stack structures ST to face each other. For example, the insulation spacers SP may be formed of a silicon oxide, a silicon nitride, a silicon oxy nitride, or a low-k material having a low dielectric constant.

In each of the first memory block MB1 and the second memory block MB2, the capping insulating film CAP may be provided on the stack structures ST, the vertical channel structures VS, and the common source plug CSP. The capping insulating film CAP may cover the upper surface of the uppermost one of the interlayer insulating films ILD, the upper surface of the conductive pad PAD, and the upper surface of the common source plug CSP. The capping insulating film CAP may be formed of an insulating material different from that of the interlayer insulating films ILD. The bit line contact plug BLPG electrically connected to the conductive pad PAD may be provided inside the capping insulating film CAP. The bit line contact plug BLPG may have a shape of which widths in the first direction D1 and the second direction D2 increase toward the third direction D3.

In each of the first memory block MB1 and the second memory block MB2, the bit line BL may be provided on the capping insulating film CAP and the bit line contact plug BLPG. The bit line BL may correspond to any one of the plurality of bit lines and may be formed of a conductive material to extend in the first direction D1. The conductive material constituting the bit line BL may be the same material as the conductive material forming each of the gate electrodes EL1, EL2, and EL3.

In each of the first memory block MB1 and the second memory block MB2, the bit line BL may be electrically connected to the vertical channel structures VS through the bit line contact plug BLPG. Here, the fact that the bit line BL is connected to the vertical channel structures VS may mean that the bit line BL is connected to the vertical channel pattern VCP included in the vertical channel structures VS.

In each of the first memory block MB1 and the second memory block MB2, the three-dimensional flash memory having such a structure may perform the program operation, the read operation, and the erase operation based on the voltage applied to each of the cell strings CSTR, the voltage applied to the string selection line SSL, the voltage applied to each of the word lines WL0 to WLn, the voltage applied to the ground selection line GSL, and the voltage applied to the common source line CSL. For example, the three-dimensional flash memory may perform the program operation by forming a channel in the vertical channel pattern VCP and transferring charges or holes to the data storage pattern DSP of the target memory cell, based on the voltage applied to each of the cell strings CSTR, the voltage applied to the string selection line SSL, the voltage applied to each of the word lines WL0 to WLn, the voltage applied to the ground selection line GSL, and the voltage applied to the common source line CSL.

Further, the three-dimensional flash memory according to another embodiment is not limited or restricted to the described structure, and may be implemented in various structures assuming that each of the first memory block MB1 and the second memory block MB2 includes the vertical channel pattern VCP, the data storage pattern DSP, the gate electrodes EL1, EL2, and EL3, the bit line BL, and the common source line CSL according to an implementation.

For example, the three-dimensional flash memory may be implemented in a structure including the back gate BG instead of the vertical semiconductor pattern VSP in contact with the inner wall of the vertical channel pattern VCP. In this case, while at least a portion of the back gate BG is surrounded by the vertical channel pattern VCP to apply the voltage for the memory operation to the vertical channel pattern VCP, the back gate BG may be formed of a conductive material including at least one selected from a doped semiconductor (e.g., a doped silicon or the like), a metal (e.g., W (tungsten), Cu (copper), Al (aluminum), Ti (titanium), Ta (tantalum), Mo (molybdenum), Ru (ruthenium), Au (gold), or the like), a conductive metal nitride (e.g., a titanium nitride, a tantalum nitride, or the like) or the like in the vertical direction (e.g., the third direction D3).

In the three-dimensional flash memory having this structure, the first memory block MB1 and the second memory block MB2 may be arranged such that the first substrate SUB1 of the first memory block MB1 and the second substrate SUB2 of the second memory block MB2 face each other.

Accordingly, the connection pad CP may connect the first memory block MB1 and the second memory block MB2 arranged such that the substrates SUB1 and SUB2 face each other.

In particular, the connection pad CP may include the connection wiring line BLC1 of the first bit line BL1 and the connection wiring line BLC2 of the second bit line BL2.

That is, as illustrated in FIG. 4, the connection pad CP includes the connection wiring line BLC1 of the first bit line BL1 and the connection wiring line BLC2 of the second bit line BL2, and thus the first bit line BL1 of the first memory block MB1 and the second bit line BL2 of the second memory block MB2 may be connected to the connection wiring lines BLC1 and BLC2, and at the same time, the first memory block MB1 and the second memory block MB2 may be connected to each other.

As described, because the first memory block MB1 and the second memory block MB2 are connected to each other in a state in which the substrates SUB1 and SUB2 face each other, the connection wiring lines BLC1 and BLC2 of the first bit line BL1 of the first memory block MB1 and the second bit line BL2 of the second memory block MB2 may have a path extending to the connection pad CP through an inside and an outside of the memory blocks MB1 and MB2. Thus, the connection wiring line BLC1 of the first bit line BL1 and the connection wiring line BLC2 of the second bit line BL2 may have a structure in which portions thereof are included in the connection pad CP.

Further, it is illustrated in the drawings that the connection wiring line BLC1 of the first bit line BL1 and the connection wiring line BLC2 of the second bit line BL2 are independently provided on the connection pad CP such that the connection wiring lines BLC1 and BLC2 are distinguished from each other, but the present disclosure is not limited or restricted thereto, and the connection wiring lines BLC1 and BLC2 may be commonly provided. As an example, the connection pad CP may include the common connection wiring line that commonly serves as the connection wiring line BLC1 of the first bit line BL1 and the connection wiring line BLC2 of the second bit line BL2. In this case, the same electrical signal may be applied to the vertical channel structure VS connected to the first bit line BL1 and the vertical channel structure VS connected to the second bit line BL2 at the same timing through the common connection wiring line.

In this case, the connection pad CP may use the TSV to connect the first memory block MB1 and the second memory block MB2 to each other. That is, the connection pad CP may connect the first memory block MB1 and the second memory block MB2 to each other through the TSV. However, the present disclosure is not limited or restricted thereto, and the connection pad CP may connect the first memory block MB1 and the second memory block MB2 to each other through bonding.

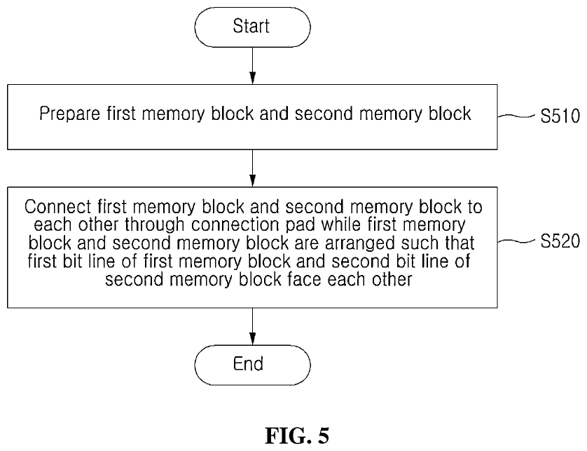

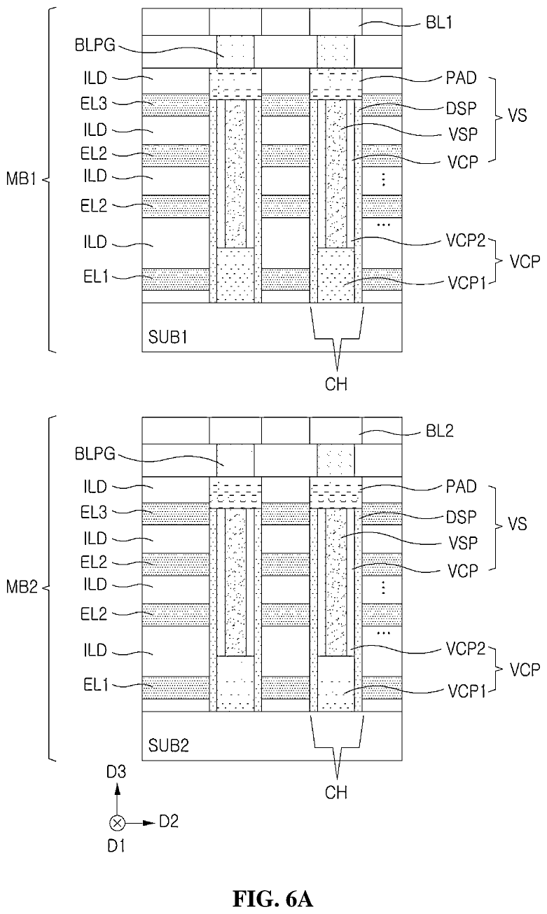

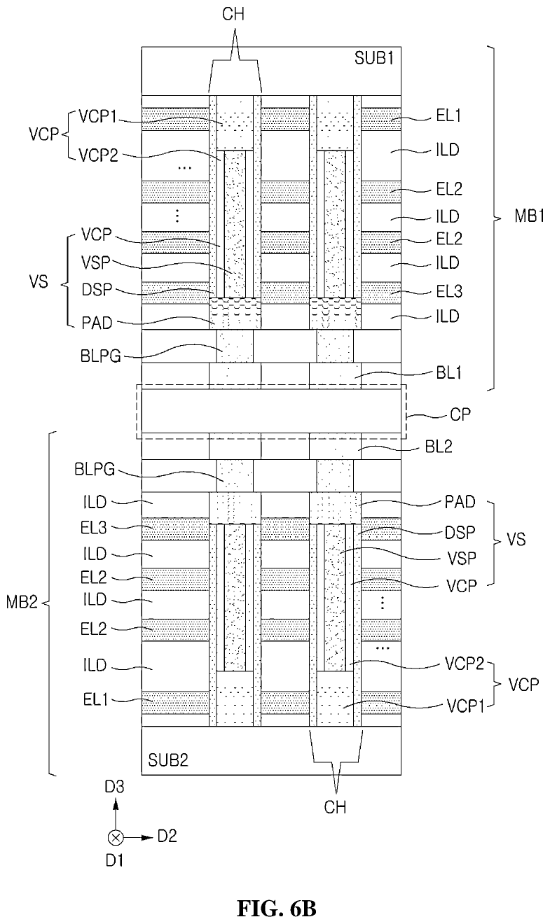

FIG. 5 is a flowchart illustrating a method of manufacturing the three-dimensional flash memory according to the embodiment, and FIGS. 6A and 6B are cross-sectional views for describing the method of manufacturing the three-dimensional flash memory illustrated in FIG. 5.

The manufacturing method described with reference to FIGS. 5, 6A, and 6B is provided to manufacture the three-dimensional flash memory having the structure described above in FIGS. 1 and 2, and a performance subject may be an automated and mechanized manufacturing system.

In operation S510, as illustrated in FIG. 6A, the manufacturing system may prepare the first memory block MB1 and the second memory block MB2.

Because the structure of each of the first memory block MB1 and the second memory block MB2 has been described above with reference to FIGS. 1 and 2, a detailed description thereof will be omitted.

In operation S520, as illustrated in FIG. 6B, the manufacturing system may connect the first memory block MB1 and the second memory block MB2 to each other through the connection pad CP while the first memory block MB1 and the second memory block MB2 are arranged such that the first bit line BL1 of the first memory block MB1 and the second bit line BL2 of the second memory block MB2 face each other.

In this case, because the connection pad CP includes the connection wiring line of the first bit line BL1 and the connection wiring line of the second bit line BL2, in operation S520, the manufacturing system may connect the first memory block MB1 and the second memory block MB2 to each other, at the same time, connect the first bit line BL1 to the connection wiring line BLC1 of the first bit line BL1, and connect the second bit line BL2 to the connection wiring line BLC2 of the second bit line BL2.

The bonding may be used as a manner in which the connection pad CP connects the first memory block MB1 and the second memory block MB2.

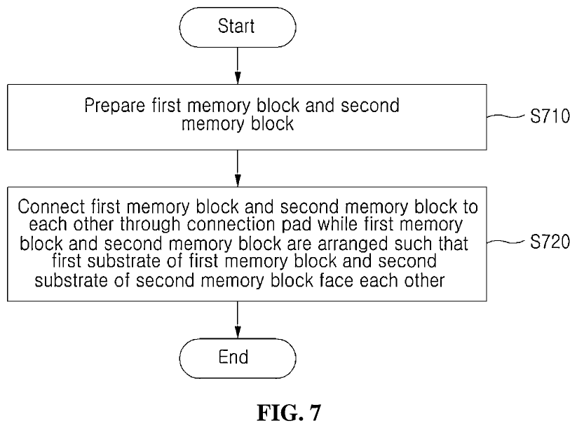

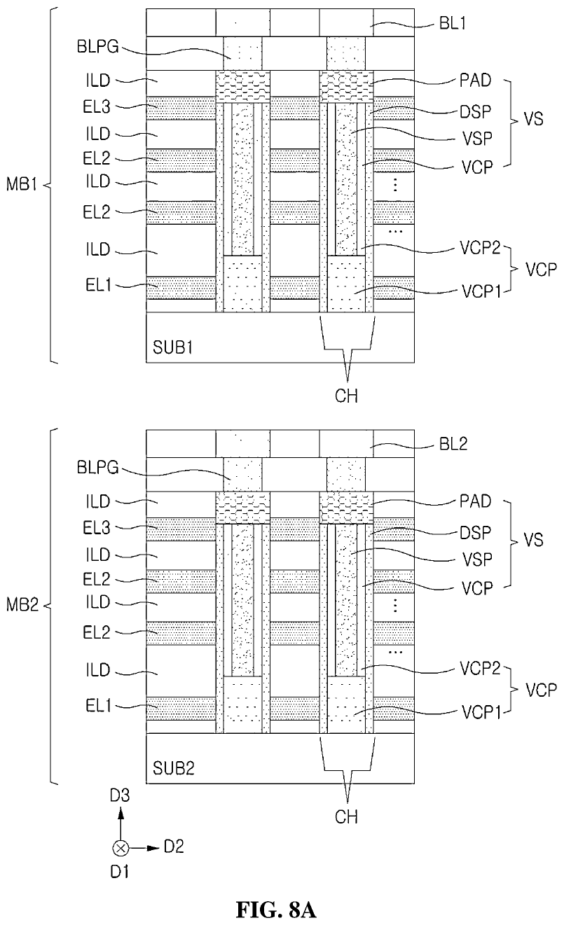

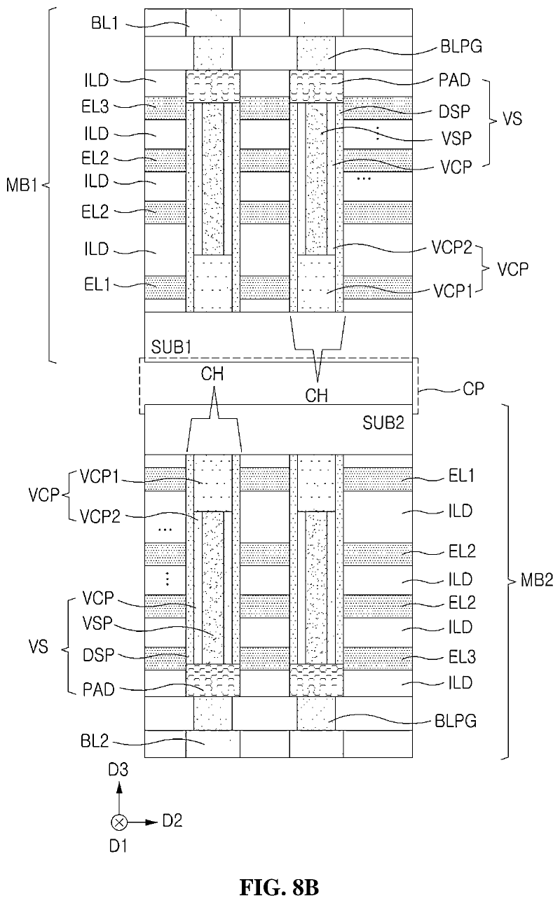

FIG. 7 is a flowchart illustrating a method of manufacturing the three-dimensional flash memory according to another embodiment, and FIGS. 8A and 8B are cross-sectional views for describing the method of manufacturing the three-dimensional flash memory illustrated in FIG. 7.

The manufacturing method described with reference to FIGS. 7, 8A, and 8B is provided to manufacture the three-dimensional flash memory having the structure described above in FIGS. 1 and 2, and a performance subject may be an automated and mechanized manufacturing system.

In operation S710, as illustrated in FIG. 8A, the manufacturing system may prepare the first memory block MB1 and the second memory block MB2.

Because the structure of each of the first memory block MB1 and the second memory block MB2 has been described above with reference to FIGS. 3 and 4, a detailed description thereof will be omitted.

In operation S720, as illustrated in FIG. 8B, the manufacturing system may connect the first memory block MB1 and the second memory block MB2 to each other through the connection pad CP while the first memory block MB1 and the second memory block MB2 are arranged such that the first substrate SUB1 of the first memory block MB1 and the second substrate SUB2 of the second memory block MB2 face each other.

In this case, because the connection pad CP includes the connection wiring line of the first bit line BL1 and the connection wiring line of the second bit line BL2, in operation S720, the manufacturing system may connect the first memory block MB1 and the second memory block MB2 to each other, at the same time, connect the first bit line BL1 to the connection wiring line BLC1 of the first bit line BL1, and connect the second bit line BL2 to the connection wiring line BLC2 of the second bit line BL2.

The TSV may be used as a manner in which the connection pad CP connects the first memory block MB1 and the second memory block MB2.

As described above, although the embodiments have been described with reference to the limited embodiments and the limited drawings, various modifications and changes may be made based on the above description by those skilled in the art. For example, even though the described technologies are performed in an order different from the described method, and/or the described components such as a system, a structure, a device, and a circuit are coupled or combined in a form different from the described method or are replaced or substituted by other components or equivalents, appropriate results may be achieved.

Therefore, other implementations, other embodiments, and those equivalent to the appended claims also belong to the scope of the appended claims.

1. A three-dimensional flash memory based on a stack process, comprising:
a first memory block including first vertical channel structures formed to extend in a vertical direction on a first substrate;
a second memory block including second vertical channel structures formed to extend the vertical direction on a second substrate; and
a connection pad connecting the first memory block and the second memory block arranged such that at least one first bit line connected to the first vertical channel structures and at least one second bit line connected to the second vertical channel structures face each other.

2. A three-dimensional flash memory based on a stack process, comprising:
a first memory block including first vertical channel structures formed to extend in a vertical direction on a first substrate;
a second memory block including second vertical channel structures formed to extend in the vertical direction on a second substrate; and
a connection pad connecting the first memory block and the second memory block arranged such that the first substrate and the second substrate face each other.

3. The three-dimensional flash memory of claim 1, wherein the connection pad includes a connection wiring line of the at least one first bit line connected to the first vertical channel structures and a connection wiring line of the at least one second bit line connected to the second vertical channel structures.

4. The three-dimensional flash memory of claim 3, wherein the connection pad is commonly provided with the connection wiring line of the at least one first bit line connected to the first vertical channel structures and the connection wiring line of the at least one second bit line connected to the second vertical channel structures.

5. The three-dimensional flash memory of claim 1, wherein the connection pad connects the first memory block and the second memory block to each other through bonding or connects the first memory block and the second memory block to each other through a through silicon via (TSV).

6. The three-dimensional flash memory of claim 2, wherein the connection pad includes a connection wiring line of the at least one first bit line connected to the first vertical channel structures and a connection wiring line of the at least one second bit line connected to the second vertical channel structures.

7. The three-dimensional flash memory of claim 6, wherein the connection pad is commonly provided with the connection wiring line of the at least one first bit line connected to the first vertical channel structures and the connection wiring line of the at least one second bit line connected to the second vertical channel structures.

8. The three-dimensional flash memory of claim 2, wherein the connection pad connects the first memory block and the second memory block to each other through bonding or connects the first memory block and the second memory block to each other through a through silicon via (TSV).
